(19) United States
(12) Patent Application Publication
(10) Pub. No.: US 2007/0067701 A1
(43) Pub. Date: Mar. 22, 2007

(54) Recording control device, recording control method and program

(76) Inventors: Tsutomu Shimosato, Tokyo (JP); Jun Sawai, Kanagawa (JP); Masaaki Hara, Tokyo (JP)

Correspondence Address: FROMMER LAWRENCE & HAUG, 745 FIFTH AVENUE- 10TH FL., NEW YORK, NY, 10151, US

(21) Appl. No.: 11/516,284

(22) Filed: Sep. 6, 2006

(30) Foreign Application Priority Data
Sep. 8, 2005 (JP) P2005-260307

(51) Int. Cl. G11C 29/00

(52) U.S. Cl. 714/770

(57) ABSTRACT

A recording control device that controls data recording in a recording medium including a plurality of recording blocks each composed of a plurality of recording units as a unit of the data recording, the recording control device comprising a recording controller configured to temporarily record after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block, the after-error data being data that originally should be recorded in the certain recording unit and in the recording unit subsequent to the certain recording unit in the predetermined recording block.

### CROSS REFERENCES TO RELATED APPLICATIONS

The embodiment of the present invention contains subject matter related to Japanese Patent Application JP 2005-260307 filed with the Japanese Patent Office on Sep. 8, 2005, the entire contents of which being incorporated herein by reference.

### BACKGROUND OF THE INVENTION

1. Field of the Invention

The present invention relates to recording control devices, recording control methods and programs, and particularly to a recording control device, a recording control method and a program that each can hendle writing errors at high speed with a small-capacity buffer memory.

2. Description of the Related Art

A NAND flash memory (hereinafter, referred to simply as a flash memory) is composed of a plurality of blocks, and each block is made up of assembly of plural pages each having a predetermined number of bytes. In the flash memory, data recording (writing) is executed page by page, and data erasing is executed block by block for example.

As shown in FIG. 1, e.g. a flash memory having a storage capacity of 2 gigabits (Gbits) includes 2048 blocks, and each one block is composed of 64 pages. Each one page is made up of 2048 bytes to which 64 bytes of a redundant part are added, i.e., total 2112 bytes.

Such flash memories are suitable for storage and carriage of large-volume data typified by image data. In recent years, the flash memories have been capable of being mounted in digital video cameras (digital cameras) and recording and reproducing devices that record content data in recording media such as hard discs and digital versatile discs (DVDs) (refer to e.g. Japanese Patent Laid-open No. Hei 10-247164).

In the flash memory, a certain number of blocks of all blocks often have already become a defective block at the shipping timing of the flash memory. The defective block refers to an unusable block, and in other words, a block in which data cannot be recorded.

Therefore, in a system incorporating a flash memory, when the flash memory is used at the first time, there is a need to check the presence (and the location) of defective blocks and execute control so as not to use detected defective blocks.

In the example of FIG. 1, a predetermined number of blocks of the total 2048 blocks are defined as the blocks allocated as alternative blocks to substitute for defective blocks, and the area including these blocks is defined as the alternative block area. For example, a block R (block indicated by symbol R) in the alternative block area is allocated as the alternative block for one defective block (not shown) detected through defect detection processing in the initial operation check, so that the data that originally should be recorded in the detected defective block is recorded in the block R.

In a flash memory, there is also a case where a block that thus far has been usable becomes a defective block during use of the flash memory, in addition to the case where defective blocks have already existed at the shipping timing of the flash memory. Specifically, when an error (writing error) has occurred at a certain page in a predetermined block in which data is being recorded, the block including the page where the error has occurred becomes a defective block from that moment. Also in this case, an alternative block is allocated to the defective block, similarly to for a defective block existing from the shipping timing.

With reference to FIG. 2, a description will be made below on conventional alternative block processing executed when an error has occurred at a certain page in a block A (block indicated by symbol A) in the flash memory with 2 Gbits shown in FIG. 1.

A controller that controls the flash memory retrieves data from a buffer memory, and then records the data in pages from a page p1, which is the beginning page of the block A, in the order of p1, p2, p3, . . . , sequentially. The following description is based on an assumption that an error has occurred when the data retrieved from the buffer memory is being recorded in a page p40. The data recorded in the pages p1 to p39 is defined as data a₁.

In this case, the controller allocates a block B (block indicated by symbol B) in the alternative block area as the alternative block for the block A. Subsequently, the controller retrieves the data a₁, which has been recorded in the pages p1 to p39 in the block A, from the buffer memory again, and records the data a₁ in pages in the block B from the beginning page thereof sequentially. After the recording of the data a₁ in pages p1 to p39 in the block B has been completed, the controller retrieves data a₂ that should be recorded in a page p40 and the subsequent pages in the block B from the buffer memory, and records the data a₂ continuously to the data a₁ in the block B.

In the above-described conventional alternative block processing, when an error has occurred at a certain page, the data corresponding to the pages from the beginning page of the block to the page where the error has occurred is retrieved from the buffer memory again. Therefore, the data to be recorded in the block needs to be held by the buffer memory until it has been confirmed that the recording of the data in all the pages in the block has been normally finished. Accordingly, it is required for the buffer memory to have at least one-block data capacity.

In addition, in the above-described alternative block processing, the data a₁, which is the data corresponding to the pages previous to the page where the error has occurred (p40), is written twice: to the blocks A and B, which lowers the speed of data recording. This recording-speed decrease causes no problem if the data to be recorded is data for which real-time processing is not needed, such as document file data. However, in a case where continuously supplied data needs to be recorded in real time like e.g. in recording of moving image data captured by a camera, this recording-speed decrease possibly leads to a serious problem in that part of images fails to be recorded, etc.

It would be possible to use a method of operating plural flash memories in parallel in order to handle the lowering of the recording speed. However, this method results in another problem of increases in the circuit scale and power consumption. When sixteen flash memories are operated in parallel for example, the capacity of the buffer memory also needs to be sixteen times that when one flash memory is operated, and hence a further increase in the capacity of the buffer memory is caused.

As described above, a buffer memory with at least one-block data capacity is sufficient for one flash memory. However, when reoccurrence of an error during rewriting due to a first error is also taken into consideration, a buffer memory with two-block data capacity needs to be prepared for one flash memory. In this case, the configuration in which sixteen flash memories are operated in parallel requires a buffer memory with a capacity of about 4 megabytes (2 blocks×2 K bytes/page×64 pages×16 flash memories).

An embodiment of the present invention is made in consideration of such a situation, and is to handle writing errors at high speed with a small-capacity buffer memory.

### SUMMARY OF THE INVENTION

According to an embodiment of the invention, there is provided a recording control device that controls data recording in a recording medium including a plurality of recording blocks each composed of a plurality of recording units as a unit of the data recording. The recording control device includes a recording controller configured to temporarily record after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block. The after-error data is data that originally should be recorded in the certain recording unit and in the recording unit subsequent to the certain recording unit in the predetermined recording block. According to an embodiment of the invention, there is provided a recording control method for implementing processing of control of data recording in a recording medium that includes a plurality of recording blocks each composed of a plurality of recording units as a unit of the data recording. The recording control method includes the step of temporarily recording after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block. The after-error data is data that originally should be recorded in the certain recording unit and in the recording unit subsequent to the certain recording unit in the predetermined recording block.

According to an embodiment of the invention, there is provided a program for causing a computer to execute processing of control of data recording in a recording medium that includes a plurality of recording blocks each composed of a plurality of recording units as a unit of the data recording. The program includes the step of temporarily recording after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block. The after-error data is data that originally should be recorded in the certain recording unit and in the recording unit subsequent to the certain recording unit in the predetermined recording block.

According to an embodiment of the invention, in control of data recording in a recording medium that includes a plurality of recording blocks each composed of a plurality of recording units as a unit of the data recording, after-error data is temporarily recorded in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block. The after-error data is data that originally should be recorded in the certain recording unit and in the recording unit subsequent to the certain recording unit in the predetermined recording block.

The recording control device may be an independent device, or may be a block executing recording control processing.

An embodiment of the invention can handle writing errors at high speed with a small-capacity buffer memory.

### BRIEF DESCRIPTION OF THE DRAWINGS

FIG. 1 is a diagram for explaining a NAND flash memory;

FIG. 2 is a diagram for explaining conventional block alternating processing;

FIG. 3 is a block diagram illustrating a configuration example of one embodiment of an information processing system to which the present invention is applied;

FIG. 4 is a block diagram illustrating a detailed configuration example of a recording device 12;

FIGS. 5A to 5C are diagrams for explaining block alternating processing by the recording device 12;

FIG. 6 is a flowchart for explaining real-time recording processing; and

FIG. 7 is a flowchart for explaining saved data recording processing.

### DETAILED DESCRIPTION OF THE PREFERRED EMBODIMENTS

An embodiment of the present invention will be described below, and the description of exemplification of the correspondence relationship between configuration elements of the invention and an embodiment described in the detailed description of the invention is as follows. This description is to confirm that an embodiment supporting the invention is described in the detailed description of the invention. Therefore, even if there is an embodiment that is not described in the following description as an embodiment corresponding to configuration elements of the invention although being described in the detailed description of the invention, this does not mean that the embodiment does not correspond to the configuration elements. On the other hand, even if an embodiment is described in the following description as an embodiment corresponding to configuration elements, this does not mean that the embodiment does not correspond to configuration elements other than the configuration elements.

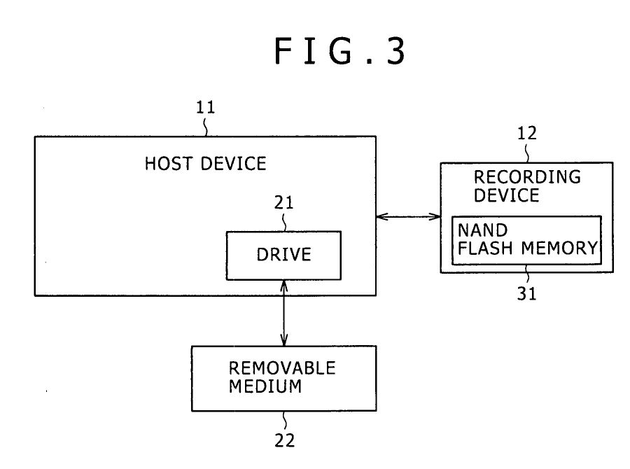

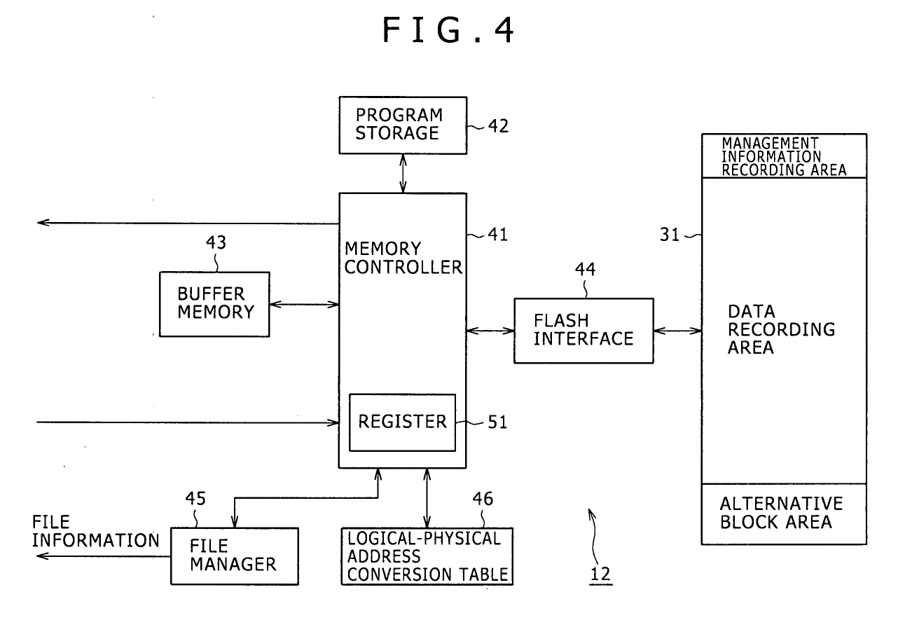

A recording control device according to an embodiment of the invention is a recording control device (e.g. a recording device 12 of FIG. 3) that controls data recording in a recording medium including a plurality of recording blocks each composed of a plurality of recording units as a unit of the data recording. The recording control device includes a recording controller (e.g. a memory controller 41 of FIG. 4) configured to temporarily record after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block. The after-error data is data that originally should be recorded in the certain recording unit and in the recording unit subsequent to the certain recording unit in the predetermined recording block.

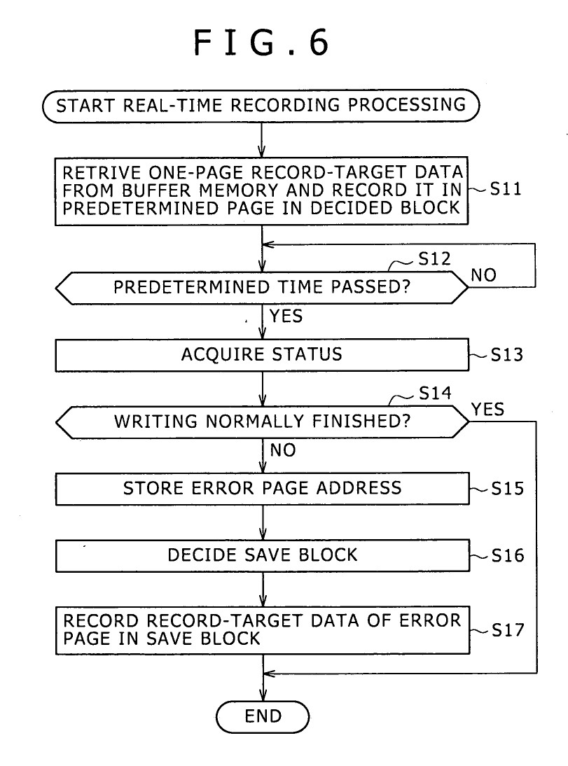

A recording control method or program according to an embodiment of the invention is a recording control method for implementing processing of control of data recording in a recording medium that includes a plurality of recording blocks each composed of a plurality of recording units as a unit of the data recording, or is a program for causing a computer to execute the processing of control of data recording. The recording control method or program includes the step (e.g. a step S17 of FIG. 6) of temporarily recording after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block. The after-error data is data that originally should be recorded in the certain recording unit and in the recording unit subsequent to the certain recording unit in the predetermined recording block.

An embodiment of the present invention will be described below with reference to the accompanying drawings.

FIG. 3 illustrates a configuration example of one embodiment of an information processing system to which the invention is applied.

The information processing system of FIG. 3 includes a host device 11 and a recording device 12.

Examples of the host device 11 include personal computers, digital video cameras (digital cameras), recording and reproducing devices for recording data (image data and so on) in recording media such as hard discs and DVDs, television receivers, cellular phones, personal digital assistants (PDAs), and portable devices such as digital audio players including a flash memory or hard disc. The host device 11 supplies the recording device 12 with data received or produced by the host device 11 so that the data is stored in the recording device 12.

Furthermore, the host device 11 includes a drive 21. Loaded in the drive 21 is a removable medium 22 that is a package medium formed of a magnetic disc (including a flexible disc), an optical disc (including a compact disc-read only memory (CD-ROM), a DVD, and a magnetooptical disc), or a semiconductor memory. The host device 11 supplies the recording device 12 with a program or data retrieved from the removable medium 22 loaded in the drive 21.

If the host device 11 includes a communication unit such as a router or modem, the host device 11 can supply the recording device 12 with a program or data acquired via the communication unit from a wired or wireless communication medium typified by a local area network, the Internet, and digital satellite broadcasting as well as a program or data retrieved from the removable medium 22.

The recording device 12 includes a NAND flash memory 31 as a recording medium, and records (stores) data (e.g. image data) supplied from the host device 11 in the NAND flash memory 31. The NAND flash memory 31 is composed of a plurality of blocks like the above description, and each block is made up of assembly of plural pages each having a predetermined number of bytes.

FIG. 4 is a block diagram illustrating a detailed configuration example of the recording device 12.

The recording device 12 includes the NAND flash memory 31, a memory controller 41, a program storage 42, a buffer memory 43, a flash interface 44, a file manager 45, and a logical-physical address conversion table 46.

As shown in FIG. 4, the NAND flash memory 31 (hereinafter, referred to simply as the flash memory 31) includes a management information recording area, a data recording area, and an alternative block area.

Stored in the management information recording area are the attribute information (configuration information such as the storage capacity, the number of blocks, and the number of pages per one block) of the flash memory 31, data information that indicates details of recorded data and the blocks including the recorded data, block information that indicates whether the blocks are in the in-use state, in the not-in-use state, or a defective block, and logical-physical address conversion information that indicates the correspondences between the physical addresses and logical addresses of the flash memory 31.

In the data recording area, data supplied from the host device 11 (hereinafter, referred to as record-target data accordingly) is recorded. The alternative block area is the area of the blocks allocated as alternative blocks for defective blocks that already exist at the shipping timing or arise during use of the flash memory.

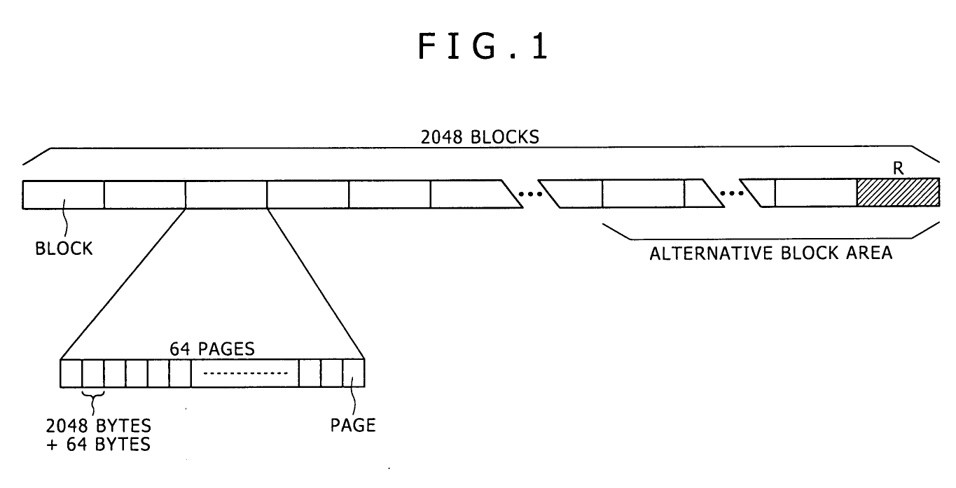

The following description is based on an assumption that the flash memory 31 has the same storage capacity and alternative block area as those of the conventional memory of FIG. 1.

The memory controller 41 controls the respective units in the recording device 12 in accordance with a control program stored in the program storage 42. Temporary data of the control of the respective units is stored in a register 51 according to need.

When the recording device 12 is activated, the memory controller 41 retrieves the attribute information, data information, block information, and logical-physical address conversion information stored in the management information recording area of the flash memory 31. Subsequently, the memory controller 41 causes the file manager 45 to store therein the attribute information, data information, and block information, and causes the logical-physical address conversion table 46 to store therein the logical-physical address conversion information. The attribute information and data information stored in the file manager 45 are integrally referred to as file information, hereinafter.

The memory controller 41 acquires record-target data and a logical address (block address) of the flash memory 31 as the record destination of the record-target data, supplied from the host device 11 (FIG. 3) together with a command of a recording instruction to the memory controller 41. The host device 11 can specify empty blocks with reference to the file information stored in the file manager 45.

The memory controller 41 stores the supplied record-target data in the buffer memory 43 temporarily, and refers to the logical-physical address conversion information stored in the logical-physical address conversion table 46 to thereby convert the logical address specified by the host device 11 into a physical address. Subsequently, for the block corresponding to the physical address resulting from the conversion, the memory controller 41 retrieves the record-target data from the buffer memory 43 one-page data by one-page data, and supplies (transfers) the retrieved data to the flash memory 31 via the flash interface 44. Thus, the record-target data is written to the predetermined block (pages) in the flash memory 31. Every time the memory controller 41 transfers the record-target data of one page, the memory controller 41 checks by the status whether or not the transferred record-target data has been normally written to the predetermined page.

The program storage 42 stores therein a control program for controlling the respective units in the recording device 12. The control program stored in the program storage 42 arises from retrieval from the removable medium 22 loaded in the drive 21 and installation in the program storage 42. The buffer memory 43 temporarily stores therein record-target data supplied from the memory controller 41. The flash interface 44 relays data between the memory controller 41 and the flash memory 31.

The file manager 45 stores therein the file information (attribute information and data information) and block information supplied from the memory controller 41 as described above. Furthermore, the file manager 45 supplies the file information to the host device 11 according to need. The logical-physical address conversion table 46 stores therein the logical-physical address conversion information supplied from the memory controller 41.

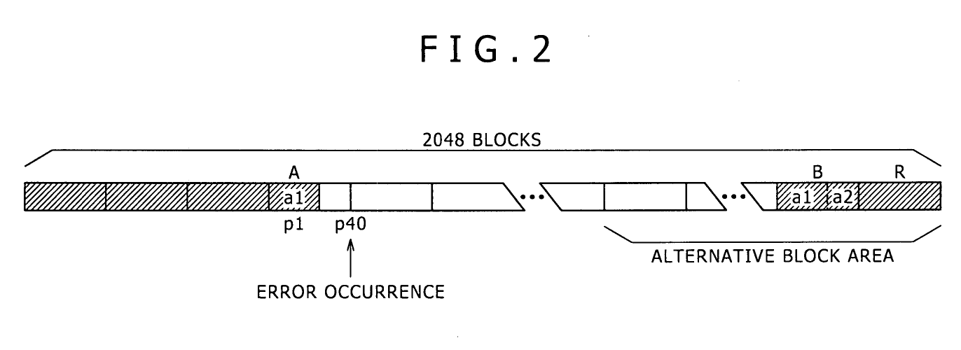

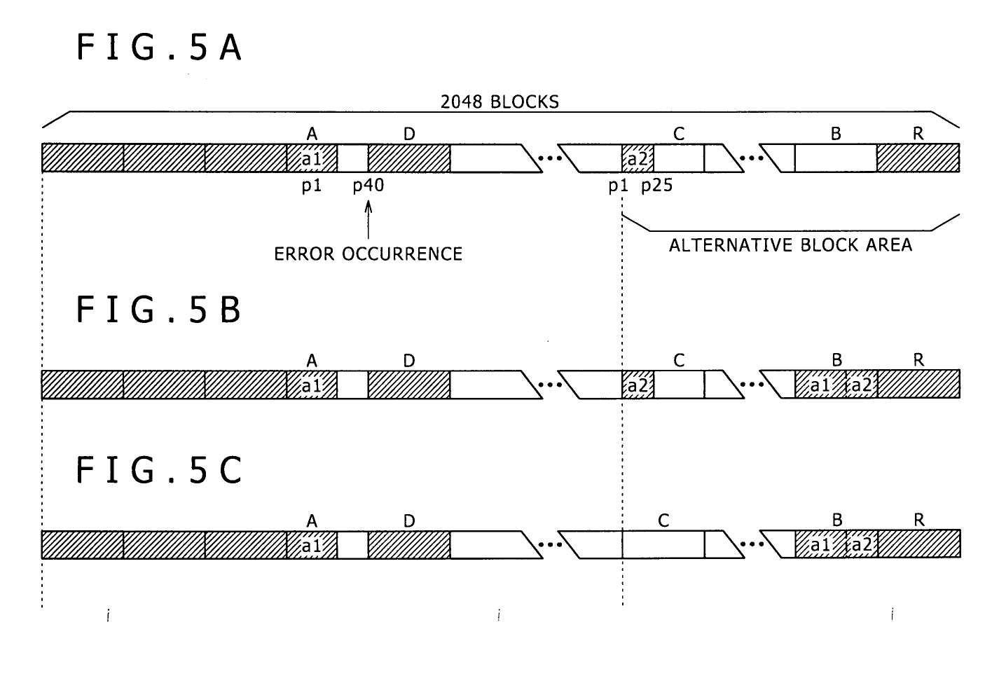

With reference to FIGS. 5A to 5C, a description will be made below on alternative block processing executed by the recording device 12 when an error (writing error) has occurred at a page p40 during writing of record-target data to a block A, similarly to the example shown in FIG. 2. The same parts in FIGS. 5A to 5C as those in FIG. 2 are given the same symbols, and the description therefor will be accordingly omitted.

Referring to FIG. 5A, the memory controller 41 retrieves record-target data from the buffer memory 43 one-page data by one-page data, and then sequentially records (transfers to the flash memory 31) the retrieved record-target data in pages from a page p1 in the block A. The following description is based on an assumption that an error has occurred when the record-target data is being recorded in the page p40 of the block A.

When an error has occurred at the page p40, the memory controller 41 stores in the register 51 the address of the page p40, where the error has occurred (error page address), and the address of the block A, where the error has occurred (error block address). Subsequently, the memory controller 41 decides, from the alternative block area, the save block to temporarily store therein data a₂ that is the record-target data that originally should be recorded in the page p40 and the subsequent pages in the block A. In FIG. 5A, a block C (block indicated by symbol C) represents the decided save block.

After the decision of the save block, the memory controller 41 retrieves the data a₂ stored in the buffer memory 43 one-page data by one-page data sequentially, and records the retrieved data in the save block C. Thus, the data a₂, which originally should be recorded in the pages p40 to p64 in the block A, is recorded in pages p1 to p25 in the save block C.

Thereafter, if record-target data exists in the buffer memory 43, the next block (e.g. a block D shown in FIG. 5A) is decided, followed by writing of the next record-target data thereto.

When recording (transfer) of the record-target data supplied from the host device 11 in the flash memory 31 has been finished temporarily, and neither writing of record-target data to the flash memory 31 nor retrieval of data recorded in the flash memory 31 is carried out, i.e., when the recording device 12 is in the idle state, the memory controller 41 executes processing shown in FIGS. 5B and 5C.

Specifically, the memory controller 41 decides the alternative block for the block A from the blocks in the alternative block area. In FIG. 5B, a block B is decided as the alternative block for the block A. Subsequently, the memory controller 41 retrieves the error block address (address indicating the block A) and error page address (address indicating the page p40) stored in the register 51, and records in the alternative block B, data a₁ (before-error data) corresponding to the pages p1 to p39 (pages previous to the page indicated by the error page address) in the block A. Furthermore, continuously to the data a₁, the memory controller 41 records in the alternative block B the data a₂ (after-error data, i.e., data corresponding to the page indicated by the error page address and the subsequent pages) recorded in the save block C.

When the memory controller 41 retrieves data stored in the flash memory 31 and records the retrieved data in a block different from the block from which the data has been retrieved, the memory controller 41 stores in the buffer memory 43 the data retrieved from the flash memory 31 one-page data by one-page data and then records the data in pages in the alternative block B, similarly to the recording of record-target data supplied from the host device 11 in the flash memory 31.

After all the data recorded in the block A and the save block C, i.e., the data a₁ and a₂, have been recorded in the alternative block B for the block A, the memory controller 41 erases the data a₂ recorded in the save block C as shown in FIG. 5C.

As described above, according to the alternative block processing by the recording device 12, if an error has occurred at the page p40 in the block A in the middle of transferring of record-target data supplied from the host device 11 to the flash memory 31, the data a₂ corresponding to the page p40, where the error has occurred, and to the subsequent pages in the block A is stored in the save block C.

Subsequently, when the recording device 12 has entered the idle state, the block B is decided as the alternative block for the block A, followed by recording in the block B, of the data a₁ recorded in the pages before the page p40 in the block A and the data a₂ that has been recorded in the save block C and corresponds to the page p40, where the error has occurred, and to the subsequent pages in the block A.

Therefore, even if record-target data supplied from the host device 11 is data for which real-time processing is needed, such as moving image data, lowering of the recording speed can be suppressed (to an almost negligible degree), because the data that needs to be retrieved from the buffer memory 43 twice when being supplied from the recording device 12 and being recorded is only the one-page data that was originally supposed to be recorded in the page p40 in the block A.

In addition, the storage capacity of the buffer memory 43 may be as small as the one-page data volume, and hence the circuit scale and power consumption thereof can be reduced extremely compared with those of a conventional buffer memory. This advantage is more effective in e.g. portable devices for which reduction of the device size and extension of the battery-based drive time are required.

If, similarly to the above-described conventional example, sixteen flash memories are operated in parallel and a buffer memory with the storage capacity equal to the two-page data volume is prepared per one flash memory also in consideration of reoccurrence of an error during rewriting due to a first error, the total storage capacity required for the buffer memory 43 is as small as about 64 K bytes (2 pages×2 K bytes/page×16 flash memories). That is, the recording device 12 of FIG. 4 can reduce the capacity of the buffer memory to 1/64 of 4 M bytes, which is the capacity required for a buffer memory in the above-described conventional example. It is expected that the capacity of flash memories further increases in the future. The increase of the capacity of flash memories leads to a larger difference between the capacity required for a buffer memory based on conventional device and method and that required for a buffer memory based on the above-described embodiment. Therefore, the present invention will become more valuable.

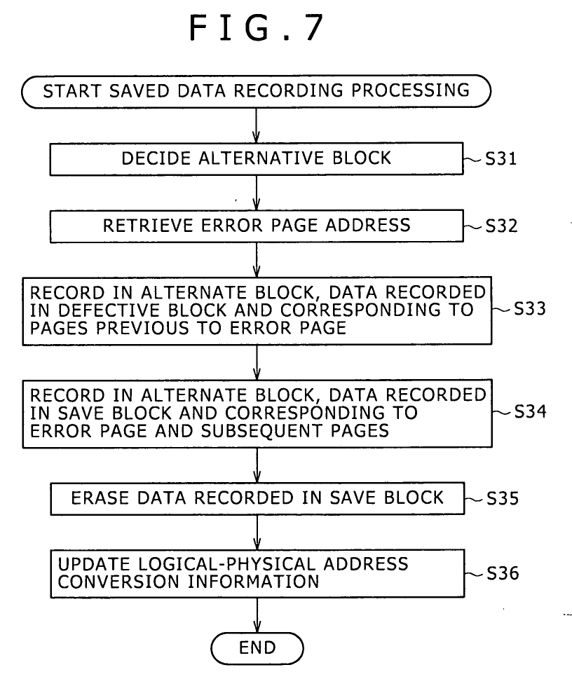

With reference to the flowcharts of FIGS. 6 and 7, a description will be made below on the block alternating processing executed by the memory controller 41 in accordance with a control program stored in the program storage 42. The block alternating processing can be divided into real-time recording processing that is executed when record-target data is supplied from the host device 11, and saved data recording processing that is executed when the recording device 12 has entered the idle state. The flowcharts of FIGS. 6 and 7 correspond to the real-time recording processing and the saved data recording processing, respectively.

When record-target data and a logical address of the flash memory 31 as the record destination of the record-target data are supplied from the host device 11 to the memory controller 41 in the recording device 12 together with a command of a recording instruction thereto, the memory controller 41 stores the supplied record-target data in the buffer memory 43, and refers to logical-physical address conversion information stored in the logical-physical address conversion table 46 to thereby convert the logical address specified by the host device 11 into a physical address. Furthermore, the memory controller 41 decides a (initial) block of the physical address resulting from the conversion. Hereinafter, the block decided by the memory controller 41 is referred to as a decided block.

Initially, in a step S11, the memory controller 41 retrieves record-target data of one page from the buffer memory 43, and supplies (transfers) the data to the flash-memory 31 via the flash interface 44 so that the data is recorded in the predetermined page (at the first time, in the beginning page) in the decided block, followed by a step S12.

In the step S12, the memory controller 41 determines whether or not a preset certain time period has passed from the transferring of the record-target data in the step S11, and waits until it is determined that the certain time period has passed.

If it is determined in the step S12 that the certain time period has passed, the processing sequence proceeds to a step S13, where the memory controller 41 acquires via the flash interface 44 from the flash memory 31 a status that indicates whether or not the transferred record-target data has been normally written to the predetermined page.

Subsequently, in a step S14, the memory controller 41 determines whether or not the writing has been normally finished based on the acquired status. If it is determined in the step S14 that the writing has been normally finished, the processing is ended.

In contrast, if it is determined in the step S14 that the writing has not been normally finished, i.e., if an error of writing to the page has occurred, the processing sequence proceeds to a step S15. In the step S15, the address of the error page (error page address), which is the page where the error has occurred, and the address of the block including the error page, i.e., a defective block, are stored in the register 51.

In a step S16, the memory controller 41 decides, from the alternative block area, the save block to temporarily store therein the record-target data that originally should be recorded in the error page and subsequent pages in the decided block, and then the processing sequence proceeds to a step S17.

In the step S17, the memory controller 41 retrieves the record-target data of the error page from the buffer memory 43 again, and records the data in the save block, followed by the end of the processing.

The above-described real-time recording processing is executed for the sixty-four pages in the decided block sequentially until an error (writing error) at any page occurs. If an error has occurred at any page of the sixty-four pages in the decided block, the record-target data corresponding to the error page and subsequent pages is recorded in the save block decided in the step S16 of FIG. 6, as described with reference to FIG. 5A.

If an error has occurred in writing to a certain page in the real-time recording processing of FIG. 6, the saved data recording processing of FIG. 7 is executed when the recording device 12 has entered the idle state.

Specifically, in a step S31, the memory controller 41 decides the alternative block for the block including the error page from the alternative block area, followed by a step S32. In the example shown in FIGS. 5A to 5C, due to the step S31, the block B is decided as the alternative block for the block A.

In the step S32, the memory controller 41 retrieves the error page address and the address of the defective block stored in the register 51, followed by a step S33. In the example shown in FIGS. 5A to 5C, the memory controller 41 stores in the register 51 the address of the page p40, where the error has occurred (error page address), and the address of the block A, where the error has occurred (error block address).

In the step S33, the memory controller 41 records in the alternative block the data that has been recorded in the defective block and correspond to the pages previous to the error page, followed by a step S34. In the example shown in FIGS. 5A to 5C, the memory controller 41 records in the alternative block B the data a₁ corresponding to the pages p1 to p39 in the block A.

In the step S34, the memory controller 41 records in the alternative block the data that has been recorded in the save block and correspond to the error page and subsequent pages, followed by a step S35. In the example shown in FIGS. 5A to 5C, due to the step S34, the data a₂, which originally should be recorded in the pages p40 to p64 in the block A, is recorded in pages p40 to p64 in the alternative block B.

In the step S35, the memory controller 41 erases the data recorded in the save block, followed by a step S36. In the example shown in FIGS. 5A to 5C, the memory controller 41 erases the data a₂ recorded in the save block C as shown in FIG. 5C.

In the step S36, the memory controller 41 updates the logical-physical address conversion information stored in the logical-physical address conversion table 46, and then ends the processing. Specifically, the memory controller 41 changes the physical address associated with the logical address of the defective block into the physical address of the alternative block, and then ends the processing. In the example shown in FIGS. 5A to 5C, the physical address associated with the logical address of the block A is changed into the physical address of the block B.

As described above, according to the block alternating processing by the recording device 12, if the block A has become a defective block due to the occurrence of an error at the page p40 when data is sequentially recorded in pages from the beginning page in the block A of the plural blocks in the flash memory 31, the memory controller 41 temporarily stores in the block C as a save block the data that originally should be recorded in the page p40 and the subsequent pages in the block A. Furthermore, when the recording device 12 is in the idle state in which neither processing of data recording in the flash memory 31 nor reproduction processing is carried out, the memory controller 41 decides the block B as the alternative recording block substituting for the block A. Subsequently, the memory controller 41 records in pages in the block B from the beginning page the data corresponding to the pages (i.e., pages p1 to p39) previous to the error page (p40) in the block A, and then continuously thereto, records the data recorded in the block C.

Thus, even when an error has occurred during the writing of record-target data supplied from the host device 11 to the flash memory 31, lowering of the recording speed can be suppressed. Furthermore, the buffer memory 43 for temporarily storing therein record-target data to be recorded in the flash memory 31 can be constructed to have a small capacity, which allows circuit scale reduction and power saving.

In the above-described example, when data is recorded in a predetermined block, the data is recorded in pages from the beginning page in the block. However, if it is possible to record data in any page in a block optionally, e.g. the following recording way is also available. Specifically, when a writing error has occurred at the page p40 in the block A, the data that originally should be recorded in the page p40 and the subsequent pages in the block A is recorded in a page p40 and the subsequent pages in the block C decided as the temporary block. Subsequently, when the recording device is in the idle state, the data recorded in the block A is recorded in pages p1 to p39 in the block C. In this case, the block C can be used as the alternative block for the block A directly.

In the above-described example, a partial area in the flash memory 31 is kept as the alternative block area in advance to ensure alternative blocks for defective blocks. However, the alternative block area does not necessarily need to be kept in advance. At the timing when a defective block has been generated, a block that is not a defective block and has not been used yet may be decided from blocks in the flash memory 31 based on block-information stored in the file manager 45.

The application of the present invention is not limited to a NAND flash memory, but the invention may be applied also to another recording medium that has a plurality of recording blocks each including plural recording units as the unit of data recording, and involves the need to treat a recording block as a defective block when a writing error has occurred at one recording unit in the recording block.

In the present specification, the steps described in the flowcharts encompass not only processes that are time-sequentially executed in accordance with the described order but also processes that are not necessarily executed time-sequentially but are executed in parallel or individually.

Furthermore, in the present specification, the term system refers to the whole of a device composed of plural devices.

It should be noted that embodiments of the invention are not limited to the above-described embodiment but various modifications might be incorporated therein without departing from the scope and spirit of the invention.

What is claimed is:

1. A recording control device that controls data recording in a recording medium including a plurality of recording blocks each composed of a plurality of recording units as a unit of the data recording, the recording control device comprising
a recording controller configured to temporarily record after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block, the after-error data being data that originally should be recorded in the certain recording unit and in the recording unit subsequent to the certain recording unit in the predetermined recording block.

2. The recording control device according to claim 1, wherein
the recording controller decides an alternative recording block that substitutes for the predetermined recording block, so that before-error data that is data recorded in the recording unit previous to the certain recording unit in the predetermined recording block is sequentially recorded in recording units from a beginning recording unit in the alternative recording block, and the after-error data recorded in the save block is recorded continuously to the before-error data.

3. The recording control device according to claim 2, wherein
in an idle state in which neither processing of the data recording in the recording medium nor reproduction processing is carried out, the recording controller decides the alternative recording block so that the before-error data is sequentially recorded in the recording units from the beginning recording unit in the alternative recording block, and the after-error data is recorded continuously to the before-error data.

4. The recording control device according to claim 3, wherein
the recording controller erases the after-error data in the save block after the after-error data recorded in the save block has been recorded in the alternative recording block.

5. The recording control device according to claim 2, wherein
the save block and the alternative recording block are decided from the recording blocks that are ensured in an alternative block area to substitute for the defective block.

6. The recording control device according to claim 1, wherein
the recording medium is a NAND flash memory.

7. A recording control method for implementing processing of control of data recording in a recording medium that includes a plurality of recording blocks each composed of a plurality of recording units as a unit of the data recording, the recording control method comprising
temporarily recording after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block, the after-error data being data that originally should be recorded in the certain recording unit and in the recording unit subsequent to the certain recording unit in the predetermined recording block.

8. A program for causing a computer to execute processing of control of data recording in a recording medium that includes a plurality of recording blocks each composed of a plurality of recording units as a unit of the data recording, the program comprising
temporarily recording after-error data in one recording block of the plurality of recording blocks as a save block if a predetermined recording block of the plurality of recording blocks has become a defective block in which the data recording is impossible due to occurrence of an error at a certain recording unit during sequential recording of data in recording units from a beginning recording unit in the predetermined recording block, the after-error data being data that originally should be recorded in the certain recording unit and in the recording unit subsequent to the certain recording unit in the predetermined recording block.
